(19) United States
(12) Patent Application Publication
(10) Pub. No.: US 2024/0053668 A1
(43) Pub. Date: Feb. 15, 2024

(54) PHOTOMASK AND METHOD OF MANUFACTURING THE SAME

(71) Applicant: TAIWAN SEMICONDUCTOR MANUFACTURING COMPANY LTD., HSINCHU (TW)

(72) Inventors: CHUN-LANG CHEN, TAINAN COUNTY (TW); CHUNG-YANG HUANG, CHIAYI COUNTY (TW); SHIH-HAO YANG, TAINAN CITY (TW); CHEN-HUI LEE, TAICHUNG CITY (TW)

(21) Appl. No.: 17/818,369

(22) Filed: Aug. 9, 2022

(51) Int. Cl. G03F 1/24

(52) U.S. Cl. CPC G03F 1/24

(57) ABSTRACT

The present disclosure provides a method of manufacturing a photomask. The method includes: forming a multilayer structure on a substrate; forming a capping layer on the multilayer structure, the capping layer including a ruthenium oxide (RuO) layer; forming a light-absorbing structure on the capping layer; forming a hard mask on the light-absorbing structure; etching the light-absorbing structure to form a recess by using the hard mask as an etch mask, wherein the recess exposes a top portion of the capping layer; and performing a treatment to convert the top portion into a ruthenium nitride (RuN) layer.

### BACKGROUND

In advanced semiconductor technologies, the continuing reduction in device size and increasingly complex circuit arrangements have made the design and fabrication of integrated circuits (ICs) more challenging and costly. To pursue better device performance with smaller footprint and less power, advanced photolithographic technologies, e.g., extreme ultraviolet (EUV) lithography, have been used manufacture semiconductor devices with a relatively small line width. The EUV lithography employs a photomask to control the irradiation of a substrate under EUV radiation so as to form a pattern on the substrate.

While existing photolithographic techniques have been improved, they still fail to meet requirements in many aspects. For example, degradation of materials of a photomask has raised several issues. Therefore, there is still a need to improve the existing photolithographic techniques.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, dimensions of the various features may be arbitrarily increased or reduced for clarity of discussion.

FIG. 1 is a schematic cross-sectional view of an EUV photomask, in accordance with some embodiments of the disclosure.

FIG. 2 is a flow diagram showing a method of manufacturing the EUV photomask shown in FIG. 1, in accordance with some embodiments of the disclosure.

FIGS. 3 to 14 are schematic cross-sectional views illustrating sequential operations of the method shown in FIG. 2, in accordance with some embodiments of the disclosure.

FIGS. 15 and 16 are schematic views showing a situation when the EUV photomask formed in FIG. 12 is in operation

FIG. 17 is a schematic view showing a situation when the EUV photomask 10 formed in FIG. 14 is in operation, in accordance with some embodiments of the disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context. In addition, the term “source/drain region” or “source/drain regions” may refer to a source or a drain, individually or collectively dependent upon the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from normal deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages, such as those for quantities of materials, durations of times, temperatures, operating conditions, ratios of amounts, and the likes thereof disclosed herein, should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

EUV lithography is an optical lithographic technology using a range of extreme ultraviolet wavelengths, roughly spanning a 2% full width at half maximum (FWHM) bandwidth about 13.5 nanometers (nm), to produce a pattern by exposing reflective photomask to UV light which gets reflected onto a substrate covered by photoresist. An EUV photomask is typically a reflective mask that includes circuit patterns and transfers the patterned EUV radiation onto the wafer through reflection of incident EUV radiation during a photolithographic operation. The layout of the EUV photomask includes an imaging region in which the circuit pattern is disposed. The photomask at least includes a light-absorption layer over a light-reflective layer, in which the light-absorption layer is patterned to form the circuit pattern thereon. The photomask generally includes a capping layer between the light-absorption layer and the light-reflective layer. The patterned EUV light is reflected from the light-reflective layer, through the capping layer and the patterned light-absorption layer, and radiated onto the wafer. The photolithographic performance of the EUV photomask is sensitive to refractive index of materials of the photomask. Many reasons may result in changing in refractive index of the materials of the photomask, and one of them is change in materials. It is studied and found that degradation or oxidation of reflective materials of a photomask may happen over times of exposure under EUV light.

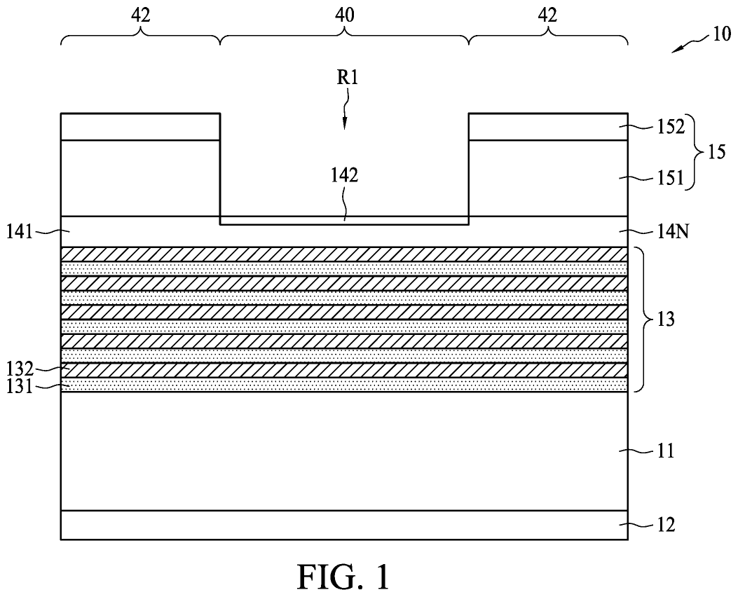

FIG. 1 is a schematic cross-sectional view of an EUV photomask 10. The EUV photomask 10 includes a substrate 11. The substrate 11 has a first surface 11A and a second surface 11B opposite to the first surface 11A. A conductive layer 12 is disposed on the second surface 11B of the substrate 11. The conductive layer 12 has a surface area substantially equal to a surface area of the substrate 11. An entirety of the conductive layer 12 is covered by the substrate 11. A multilayer structure 13 is disposed on the substrate 11. A capping layer 14N is disposed on the multilayer structure 13. A light-absorbing structure 15 which includes a recess R1 is disposed on the capping layer 14N. The capping layer 14N includes a ruthenium oxide (RuO) layer 141 and a ruthenium nitride (RuN) layer 142 disposed on the RuO layer 141. The RuN layer 142 is exposed by the recess R1 and surrounded by the light-absorbing structure 15. The RuN layer 142 is surrounded by a portion of the RuO layer 141 below the light-absorbing structure 15. The RuN layer 142 covers another portion of the RuO layer 141 which is not below the light-absorbing structure 15. The RuO layer 141 has a substantially U-shaped profile from a cross-sectional view. The light-absorbing structure 15 includes a first absorbing layer 151 disposed on the capping layer 14 and a second absorbing layer 152 disposed on the first absorbing layer 151. The first absorbing layer 151 includes TaBN, and the second absorbing layer 152 includes TaBO. The first absorbing layer 151 surrounds the RuN layer 142. The light-absorbing structure 15 has a plurality of reflective regions 40 (one reflective region 40 is shown in FIG. 1), where the first absorbing layer 151 and the second absorbing layer 152 are absent (that is, the region where the recess R1 is) and a plurality of absorptive regions 42, where the first absorbing layer 151 and the second absorbing layer 152 are present. Two reflective regions 40 is separated by one absorptive region 42. Two absorptive regions 42 is separated by one reflective region 40. The RuN layer 142 is disposed in the reflective region 40. An anti-reflective coating (ARC) layer (not shown) may be disposed on the light-absorbing structure 15.

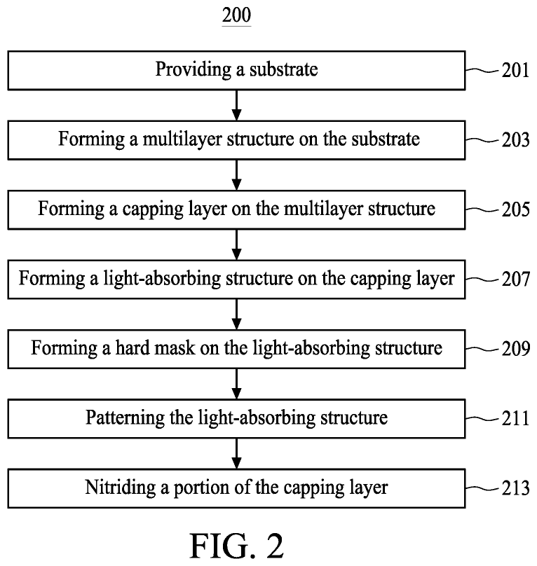

FIG. 2 is a flow diagram showing a method 200 of manufacturing the EUV photomask 10 shown in FIG. 1. The method 200 includes a number of operations (201, 203, 205, 207, 209, 211 and 203) and the description and illustration are not deemed as a limitation to the sequence of the operations. In the method 200, a substrate is provided in operation 201, a multilayer structure is formed on the substrate in operation 203, a capping layer is formed on the multilayer structure in operation 205, a light-absorbing structure is formed on the capping layer in operation 207, a hard mask is formed on the light-absorbing structure in operation 209, the light-absorbing structure is patterned in operation 211, and a portion of the capping layer is nitrided in operation 213.

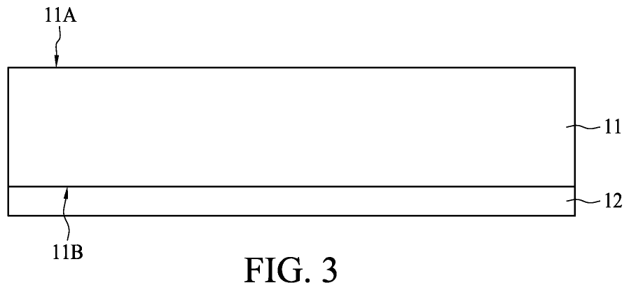

FIGS. 3 to 14 are schematic cross-sectional views illustrating sequential operations of the method 200 shown in FIG. 2. It should be noted that the operations of the method 200 may be rearranged or otherwise modified within the scope of the various aspects. Additional operations may be provided before, during or after the operations shown in FIGS. 3 to 14, and some other operations may be only briefly described herein. The order of the operations may be changed. Materials, configurations, dimensions, operations the same as or similar to those described with respect to the foregoing embodiments may be employed in the following embodiments and the detailed explanation thereof may be omitted.

In operation 201 of FIG. 2, a substrate 11 is provided, as shown in FIG. 3. The substrate 11 has a first surface 11A and a second surface 11B opposite to the first surface 11A. In some embodiments, the substrate 11 is formed of a low thermal expansion (LTE) material, such as fused silica, fused quartz, silicon, silicon carbide, black diamond and other low thermal expansion substances. In some other embodiments, the substrate 11 includes another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In yet other embodiments, the substrate 11 is a semiconductor-on-insulator (SOI) substrate. The substrate 11 may serve to reduce image distortion resulting from mask heating. In addition, the substrate 11 may include material properties of a low defect level and a smooth surface. In some embodiments, the substrate 11 transmits light at a predetermined spectrum, such as visible wavelengths, infrared wavelengths near the visible spectrum (near-infrared), and ultraviolet wavelengths. In some embodiments, the substrate 11 absorbs EUV wavelengths and DUV wavelengths.

In some embodiments, a conductive layer 12 is disposed on the second surface 11B of the substrate 11. The conductive layer 12 may aid in engaging the EUV photomask 10 to be formed with an electric chucking mechanism (not separately shown) in a photolithographic system. In some embodiments, the conductive layer 12 includes chromium nitride (CrN), chromium oxynitride (CrON), or suitable conductive materials. In some embodiments, the conductive layer 12 has a surface area substantially equal to a surface area of the substrate 11. An entirety of the conductive layer 12 may be covered by the substrate 11. In some other embodiments, the surface area of the conductive layer 12 is less than the surface area of the substrate 11.

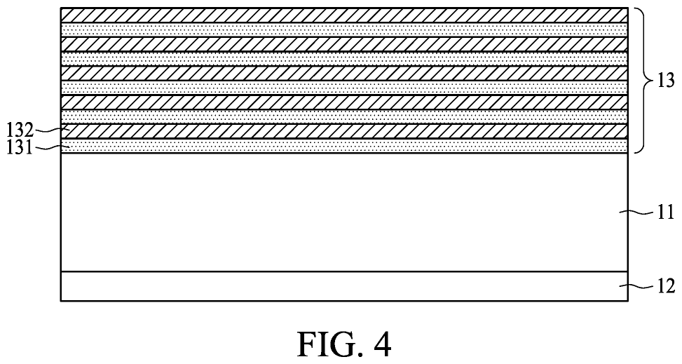

In operation 203 of FIG. 2, a multilayer structure 13 is formed on the substrate 11, as shown in FIG. 4. The multilayer structure 13 may be formed on the first surface 11A using physical vapor deposition (PVD), chemical vapor deposition (CVD), plasma-enhanced CVD (PECVD), atomic layer deposition (ALD), or other suitable operations. In some embodiments, the multilayer structure 13 is reflective. The multilayer structure 13 may serve as a radiation-reflective layer of the EUV photomask 10. The multilayer structure 13 may include a great number of alternating layers having a high refractive index and a low refractive index. A material having a high refractive index tends to scatter EUV light, and on other hand, a material having a low refractive index tends to transmit EUV light. Pairing these two type materials together provides a resonant reflectivity. In some embodiments, the multilayer structure 13 includes multiple molybdenum (Mo) layers 131 and multiple silicon (Si) layers 132 alternately arranged with each other. That is, the multilayer structure 13 includes multiple repeated pairing layers, in which each pairing layer includes a Mo layer 131 and a Si layer 132 (i.e., a Mo/Si paring layer). The thickness of each layer of the multilayer structure 13 depends on the EUV wavelength and the incident angle. The thickness of the multilayer structure 13 may be adjusted to achieve a maximum constructive interference of the EUV light reflected at each interface and a minimum absorption of the EUV light by the multilayer structure 13.

In some embodiments, the reflectivity of the multilayer structure 13 is greater than about 60% for wavelengths of interest e.g., 13.5 nm. In some embodiments, the number of the Mo/Si paring layers of the multilayer structure 13 is between about 142 and about 80, e.g., 40. Further, in some embodiments, each of the Mo layers 131 or each of the Si layers 132 has a thickness between about 2 nm and about 10 nm. In some embodiments, the Mo layers 131 and the Si layers 132 have substantially equal thicknesses. In alternative embodiments, the Si layers 132 and the Mo layers 131 have different thicknesses. In some embodiments, a thickness each of the Mo layers 131 is substantially greater than that of each of the Si layers 132, e.g. by 1 nm.

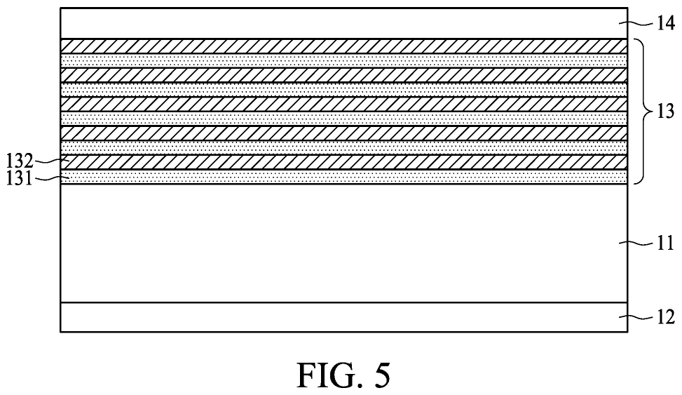

In operation 205 of FIG. 2, a capping layer 14 is formed on the multilayer structure 13, as shown in FIG. 5. In some embodiments, the capping layer 14 is a ruthenium (Ru)-based layer such as a Ru metal layer or a ruthenium oxide (RuO) layer. The ruthenium atoms of the capping layer 14 may naturally react with oxygen (O₂) in the atmosphere to form ruthenium oxide. The capping layer 14 may be formed using PVD, CVD, low-temperature CVD (LTCVD), ALD or other suitable operations. In some other embodiments, the capping layer 14 includes silicon dioxide (SiO₂), amorphous carbon or other suitable compositions. In some embodiments, the capping layer 14 has a thickness between about 1 nm and about 10 nm. The capping layer 14 may be used to prevent oxidation of the multilayer structure 13 during a mask patterning operation or a repairing operation of a light-absorbing layer that is subsequently formed. In addition, the capping layer 14 may act as an etch stop layer (ESL) in a patterning operation of the light-absorbing layer.

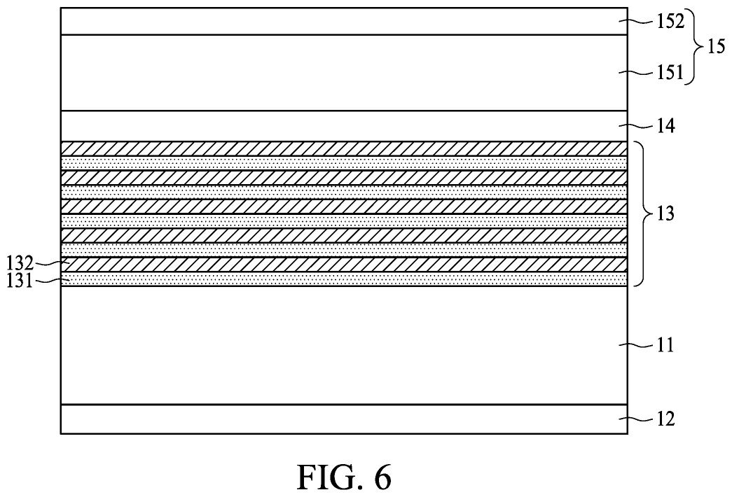

In operation 207 of FIG. 2, a light-absorbing structure 15 is formed on the capping layer 14, as shown in FIG. 6. The light-absorbing structure 15 may include chromium (Cr), chromium oxide (CrO), titanium nitride (TiO), tantalum nitride (TaN), tantalum oxide (TaO), tantalum boron (TaB), tantalum boron nitride (TaBN), tantalum boron oxide (TaBO), tantalum (Ta), titanium (Ti), aluminum-copper (Al—Cu), combinations thereof, or the like. The light-absorbing structure 15 may be formed using PVD, CVD, LTCVD, ALD or other suitable operations.

The light-absorbing structure 15 may be formed of multiple layers. For example, the light-absorbing structure 15 may be formed by a dual-layer of low-reflectivity TaBN and low-reflectivity TaBO. In some embodiments, the light-absorbing structure 15 includes a first absorbing layer 151 formed on the capping layer 14 and a second absorbing layer 152 formed on the first absorbing layer 151. In some embodiments, the first absorbing layer 151 includes TaBN, and the second absorbing layer 152 includes TaBO. The first absorbing layer 151 and the second absorbing layer 152 may have different etch characteristics (for example, etch rates). The light-absorbing structure 15 may have a different etch characteristic from that of the capping layer 14. The first absorbing layer 151 and the second absorbing layer 152 may have adequate overetch tolerance, a controllable etch profile and a negligible etch bias.

In some embodiments, the light-absorbing structure 15 is an anti-reflective layer. The light-absorbing structure 15 may absorb radiation in the EUV wavelength range projected onto the EUV photomask 10. The light-absorbing structure 15 may be any suitable thickness for a given material to achieve an adequate absorption. In some embodiments, the light-absorbing structure 15 has a thickness in a range between about 10 nm and about 100 nm, or between about 40 nm and about 80 nm, e.g., 70 nm. In some embodiments, a thickness of the first absorbing layer 151 is greater than a thickness of the second absorbing layer 152. In some embodiments, the thickness of the first absorbing layer 151 is in a range between about 5 nm and about 70 nm. In some embodiments, the thickness of the second absorbing layer 152 is in a range between about 5 nm and about 50 nm.

Prior to the deposition of the hard mask layer 16A, in some embodiments, an anti-reflective coating (ARC) layer (not shown) is formed on the light-absorbing structure 15. The ARC layer may be used to reduce the reflection of a lithographic radiation having a wavelength shorter than the DUV range from the light-absorbing structure 15. The antireflective layer may include chromium (III) oxide (Cr₂O₃), indium tin oxide (ITO), silicon nitride (SiN), tantalum pentoxide (TaO₅), other suitable materials, or a combination thereof. The antireflective layer may be formed using PVD, CVD, LTCVD, ALD, or other suitable operations.

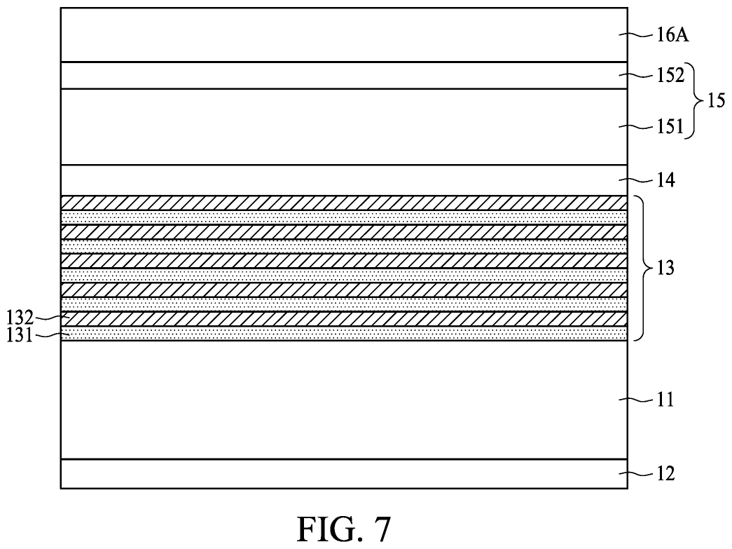

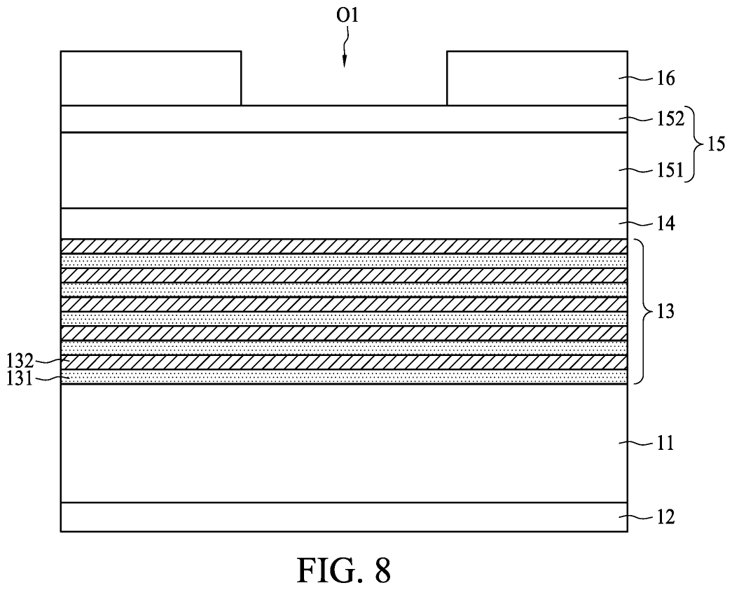

In operation 209 of FIG. 2, a hard mask 16 is formed on the light-absorbing structure 15, as shown in FIGS. 7 and 8. Referring to FIG. 7, a hard mask layer 16A is deposited on the light-absorbing structure 15 using spin coating, CVD, PVD, ALD, or other suitable operations. The hard mask layer 16A may be made of a silicon-based compound, a chromium-based compound, other suitable materials, or a combination thereof. In some embodiments, the chromium-based compound includes chromium (III) oxide, chromium nitride (CrN), chromium oxynitride (CrOₓN_{y}), or other suitable materials.

Referring to FIG. 8, the hard mask layer 16A is patterned to form the hard mask 16. The hard mask 16 may include one or more openings O1. These openings O1 may penetrate the hard mask layer 16A and expose portions of the underlying light-absorbing structure 15. Although FIG. 8 shows the hard mask 16 has an opening O1, the hard mask 16 may have multiple openings O1 that are not shown for simplicity. To form the hard mask 16, a patterned photoresist (not shown) may be formed on the hard mask layer 16A. The patterned photoresist may have patterns corresponding to a predetermined circuitry. The patterns may be formed using electron-beam (E-beam) writing, ion-beam writing, or other suitable methods. Subsequently, the hard mask layer 16A is etched using the patterned photoresist as an etch mask. The etch operation may be dry etch or reactive ion etch (RIE). The etch operation may stop at an exposure of the second absorbing layer 152, and thus the hard mask 16 is formed.

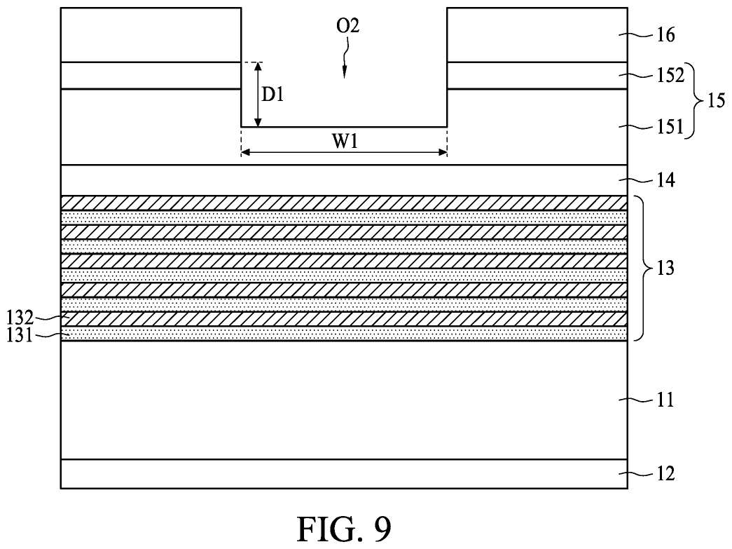

In operation 211 of FIG. 2, the light-absorbing structure 15 is patterned, as shown in FIGS. 9 to 12. Referring to FIG. 9, a first etch operation is performed on the light-absorbing structure 15. The first etch operation may include dry etch or reactive ion etch (RIE) using the hard mask 16 as an etch mask. In some embodiments, the first etch operation is used to remove portions of the second absorbing layer 152 and the first absorbing layer 151, and thereby forming an opening O2. Since the first absorbing layer 151 and the second absorbing layer 152 are made of different materials, a first etch gas may be used to etch the material of the second absorbing layer 152 and a second etch gas different from the first etch gas may be used to etch the material of the first absorbing layer 151. The opening O2 is surrounded by portions of the second absorbing layer 152 and the first absorbing layer 151. In some embodiments, the opening O2 penetrates the second absorbing layer 152. The opening O2 is formed as a downward extension of the opening O1. The first etch operation may remove a surficial portion of the first absorbing layer 151 without penetrating the first absorbing layer 151. The opening O2 may have a depth D1 starting from a top surface of the light-absorbing structure 15 and a width W1.

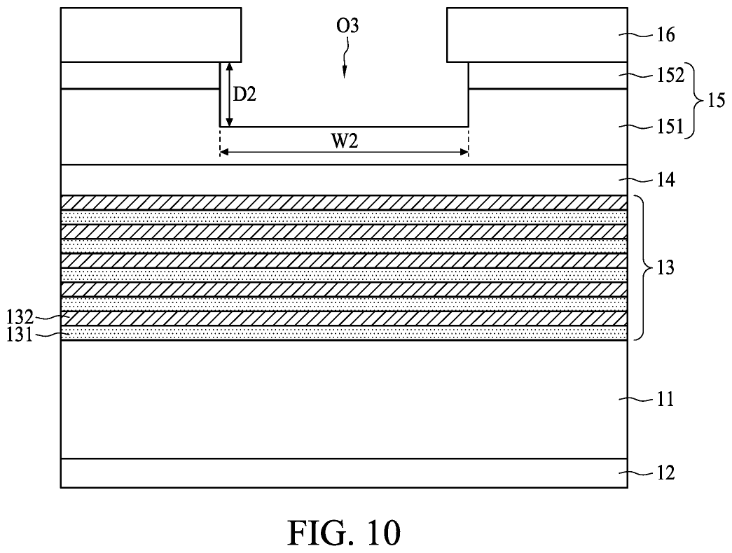

Referring to FIG. 10, a second etch operation is performed on the light-absorbing structure 15. The second etch operation may include dry etch, RIE or directional etch using the hard mask 16 as an etch mask. In some embodiments, the second etch operation is performed for a purpose of controlling critical dimensions (CD) of patterns on the EUV photomask 10 to be formed. Etchants of the second etch operation may react with the light-absorbing structure 15 from the opening O2. In some embodiments, portions of the second absorbing layer 152 and the first absorbing layer 151 exposed by the opening O2 are laterally removed during the second etch operation. The opening O2 is gradually enlarged to form an opening O3 which is surrounded by portions of the second absorbing layer 152 and the first absorbing layer 151. The second etch operation may further remove a surficial portion of the first absorbing layer 151 without penetrating the first absorbing layer 151. The opening O3 may have a depth D2 starting from the top surface of the light-absorbing structure 15 and a width W2. The depth D2 may be greater than the depth D1, and the width W2 may be greater than the width W1.

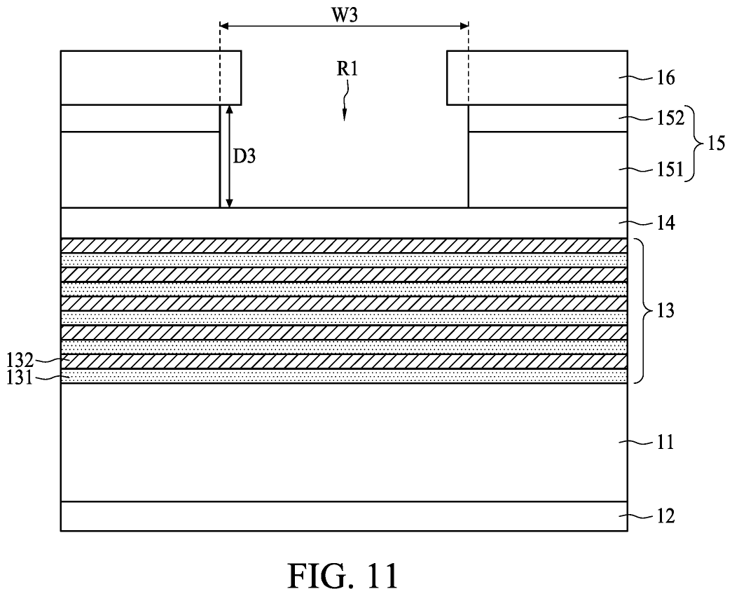

Referring to FIG. 11, a third etch operation is performed on the light-absorbing structure 15. The third etch operation may include dry etch, RIE or directional etch using the hard mask 16 as an etch mask. A portion of the first absorbing layer 151 is further etched until the first absorbing layer 151 is penetrated, and thereby forming a recess R1. The third etch operation may stop at an exposure of the capping layer 14. The recess R1 is surrounded and defined by a portion of the second absorbing layer 152 and a portion of the first absorbing layer 151. The recess R1 may expose a top portion of the underlying capping layer 14. The recess R1 may be a through hole penetrating the light-absorbing structure 15. The recess R1 may have a depth D3 starting from the top surface of the light-absorbing structure 15 and a width W3. The depth D3 may be substantially equal to the thickness of the light-absorbing structure 15 and greater than the depth D2. The width W3 may be greater than or equal to the width W2.

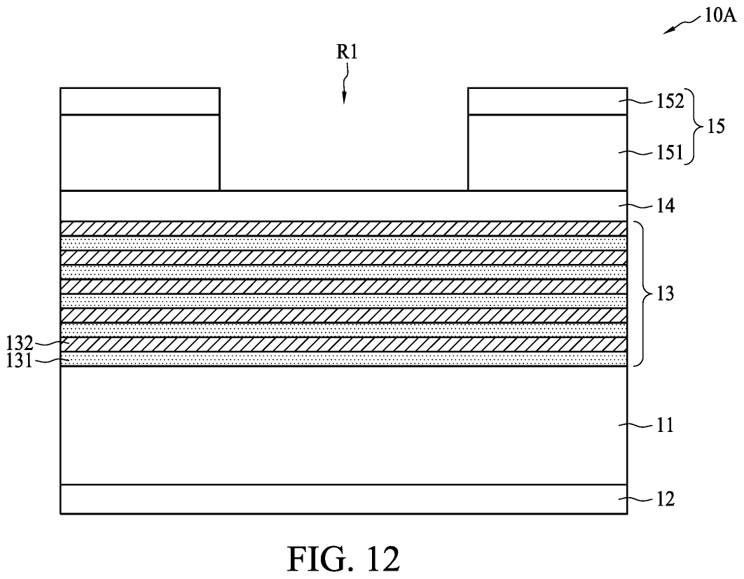

Referring to FIG. 12, the hard mask 16 is removed. The removal of the hard mask 16 may include an etching operation or an ashing operation. At this stage, a EUV photomask 10A is formed. The EUV photomask 10A includes the multilayer structure 13 disposed on the substrate 11, the capping layer 14 disposed on the multilayer structure 13, and the light-absorbing structure 15 disposed on the capping layer 14. The light-absorbing structure 15 includes the recess R1 which partially exposes a top portion of the capping layer 14. The light-absorbing structure 15 includes the first absorbing layer 151 and the second absorbing layer 152 disposed on the first absorbing layer 151.

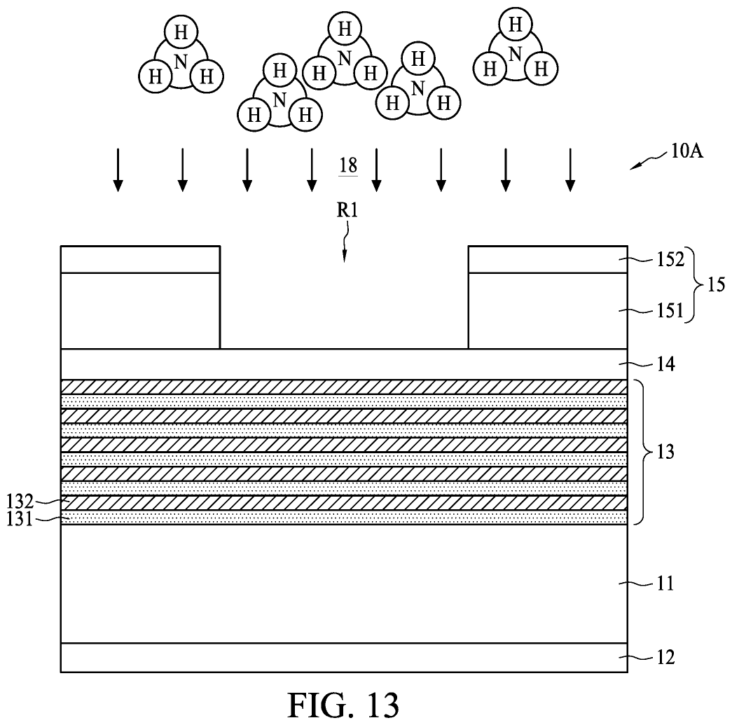

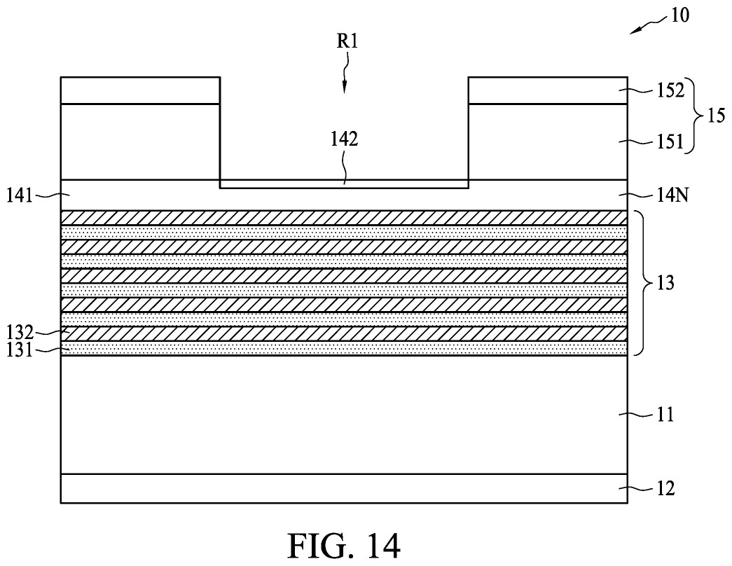

In operation 213 of FIG. 2, a portion of the capping layer 14 is nitrided, as shown in FIGS. 13 and 14. Referring to FIG. 13, a nitriding treatment 18 may be applied to the capping layer 14. In some embodiments, the nitriding treatment 18 includes injecting ammonia (NH 3) into a chamber where the EUV photomask 10A is disposed and decomposing the ammonia. A plasma treatment or a heat treatment may be used to decompose the ammonia into nitrogen (N 2) and hydrogen (H 2). In some embodiments, the plasma treatment includes using atmospheric pressure (AP) plasma or inductive couple plasma (ICP). The nitrogen may diffuse to a top portion of the capping layer 14 exposed by the recess R1 and react with the ruthenium oxide of the capping layer 14. In some embodiments, the nitriding treatment 18 lasts for about 100 seconds (s) to 500 s. The nitriding treatment 18 may be a deoxygenation reaction, in which oxygen atoms of the top portion of the exposed capping layer 14 are replaced by nitrogen atoms. In such embodiments, the ruthenium oxide (RuO) of the top portion of the exposed capping layer 14 is converted into ruthenium nitride (RuN).

Referring to FIG. 14, a portion of the capping layer 14 which is not nitrided remains a RuO layer 141, while the other portion of the capping layer 14 which is nitrided becomes a RuN layer 142. The capping layer 14 after the nitriding treatment 18 is converted to a capping layer 14N. The capping layer 14N includes the RuO layer 141 and the RuN layer 142 disposed on the RuO layer 141. In some embodiments, the RuN layer 142 has a thickness that is about 0.01 to about 0.8 times the thickness of the capping layer 14N. The RuN layer 142 may be exposed by the recess R1 and surrounded by the light-absorbing structure 15. The RuN layer 142 may be surrounded by a portion of the RuO layer 141 below the light-absorbing structure 15. The RuN layer 142 may cover another portion of the RuO layer 141 which is not below the light-absorbing structure 15. In some embodiments, the RuO layer 141 has a substantially U-shaped profile from a cross-sectional view. At this stage, the EUV photomask 10 is formed. The EUV photomask 10 may incorporate other resolution enhancement techniques such as an optical proximity correction (OPC). The EUV photomask 10 may undergo a defect repair process by a repair system. The mask repair system is a suitable system, such as an e-beam repair system and/or a focused ion beam (FIB) repair system.

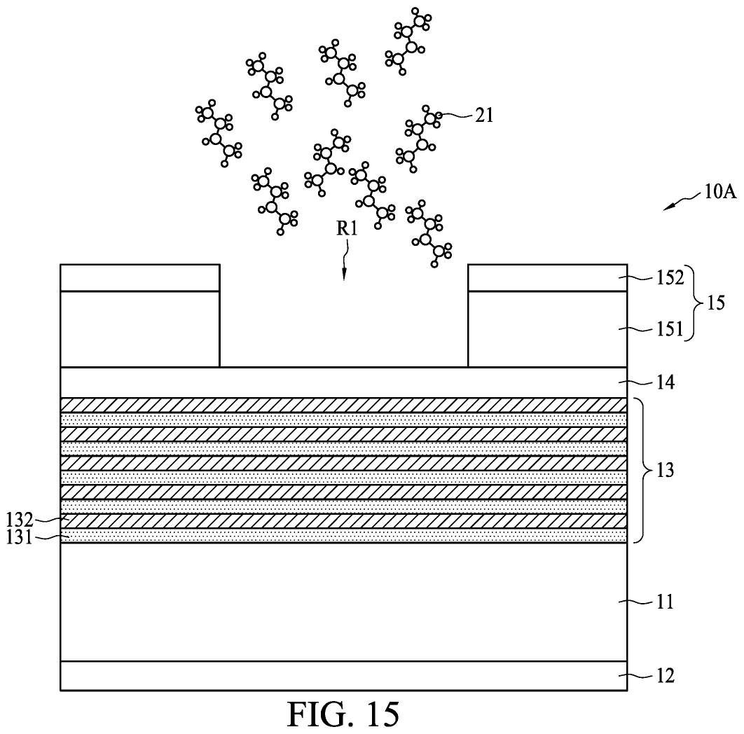

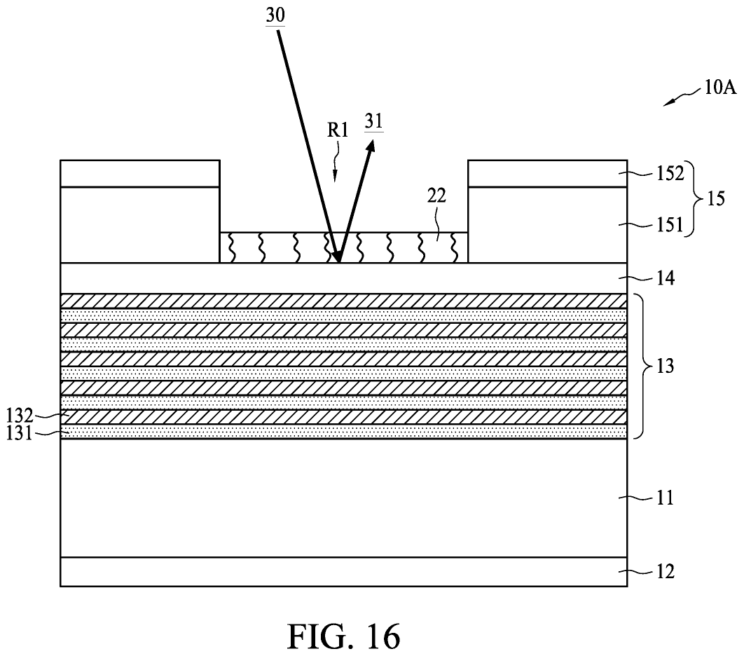

FIGS. 15 and 16 are schematic views showing a situation when the EUV photomask 10A formed in FIG. 12 is in operation. The EUV photomask 10A works by reflecting light. Referring to FIG. 15, when an EUV scanner is used in a photolithographic operation, hydrocarbon compounds 21 may be generated in some cases. The hydrocarbon compounds 21 may include carbon (C)-based compounds such as methane (CH₄), ethane (C₂H₄), propane (C₃H₈), or the like. These hydrocarbon compounds 21 may diffuse and stick to optic surfaces of the EUV photomask 10A. For example, referring to FIG. 16, the hydrocarbon compounds 21 may accumulate in the recess R1 and form a hydrocarbon layer 22 on the capping layer 14. The hydrocarbon layer 22 may have a strong interaction with the ruthenium oxide of the capping layer 14. As such, the hydrocarbon layer 22 may be firmly attached to the capping layer 14 during the exposure. When an incident light 30 strikes the EUV photomask 10A, the hydrocarbon layer 22 may absorb the incident light 30, reducing the intensity of a corresponding reflective light 31. The weakened reflective light 31 may lead to insufficient exposure and poor imaging performance. Such weak reflective light 31 may cause critical dimension errors or generate patterns with less width than expected. In some cases, a mixture of alkaline chemicals, an organic solvent or a UV light is used to remove hydrocarbon contaminants on an EUV photomask. However, the above chemical or light may damage the capping layer of the EUV photomask and reduce the lifetime of the EUV photomask.

Referring back to FIG. 14, the present disclosure provides a method of decreasing the interaction between hydrocarbon compounds (for example, the hydrocarbon compounds 21 in FIG. 15) and the capping layer 14N of the EUV photomask 10 by modifying a surface characteristic of the capping layer 14. The capping layer 14N which includes the RuN layer 142 may have a surface characteristic different from the capping layer 14 which does not include an RuN layer. In addition, the thickness of the RuN layer 142 is about 1% to about 80% times the thickness of the capping layer 14N. Hydrocarbon compounds may not be adhered to the capping layer 14N of the EUV photomask 10 easily.

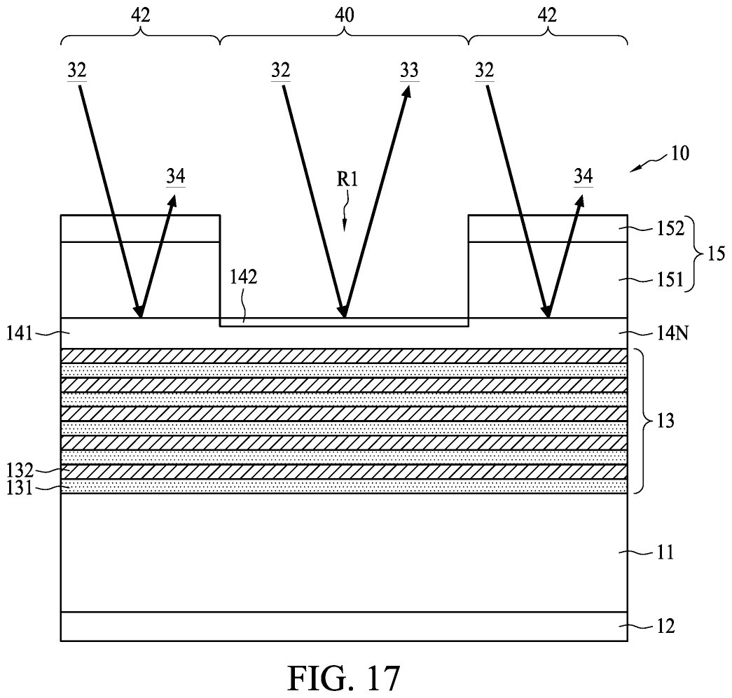

FIG. 17 is a schematic view showing a situation when the EUV photomask 10 formed in FIG. 14 is in operation. In some embodiments, the RuN layer 142 has a weak interaction with hydrocarbon compounds. An interaction between the RuN layer 142 and hydrocarbon compounds may be weaker than that between the RuO layer 141 and the same or similar hydrocarbon compounds. In some embodiments, the RuO layer 141 of the capping layer 14N is blocked by the light-absorbing structure 15, and the hydrocarbon compounds are not adhered to the RuN layer 142 easily. That is, the RuN layer 142 and the light-absorbing structure 15 isolate the RuO layer 141 from being in contact with a hydrocarbon compound in the ambient. The RuN layer 142 may prevent any carbon atom, hydrogen atom or hydrocarbon compound from reacting with or adhering to the RuO layer 141. In such embodiments, before the hydrocarbon compounds accumulate on the capping layer 14N, the hydrocarbon compounds will be sucked out by a vacuum pump. The RuN layer 142 may prevent any hydrocarbon compound or atoms of the hydrocarbon compound from reacting with or adhering to the RuO layer 141.

In some embodiments, the light-absorbing structure 15 is patterned to have a plurality of reflective regions 40 (one reflective region 40 is shown in FIG. 17), where the first absorbing layer 151 and the second absorbing layer 152 are removed (that is, the region where the recess R1 is) and a plurality of absorptive regions 42, where the first absorbing layer 151 and the second absorbing layer 152 are present. The reflective regions 40 may be arranged with the absorptive regions 42. In some embodiments, two reflective regions 40 is separated by one absorptive region 42, and two absorptive regions 42 is separated by one reflective region 40. In some embodiments, the RuN layer 142 is disposed in the reflective region 40. An incident light 32 from an EUV lithographic light source (not shown) striking the EUV photomask 10 is reflected mainly from the interfaces of the multilayer structure 13 below the light-absorbing structure 15. The reflected light from the multilayer structure 13 in the reflective region 40 forms a reflected light 33. The reflected light 33 is a patterned beam, according to the pattern defined by the light-absorbing structure 15. The reflected light 33 is collected and projected to a target substrate (e.g., a semiconductor wafer) through a projection optic system. Since there is substantially no hydrocarbon on the capping layer 14N, the intensity of a corresponding reflective light 33 will not be reduced. Therefore, the adverse effect of the hydrocarbon contaminants on the reflective region 40 can be reduced. The reflective light 33 may be used in the exposure and provide a good imaging performance. In the meantime the incident light 32 may be reflected through the light-absorbing structure 15 in the absorptive region 42 to form a reflected light 34. Since the light-absorbing structure 15 may absorb light, the intensity of the reflected light 34 is weaker than the intensity of the reflected light 33.

After the EUV photomask 10 is used for many times, some portions of the RuN layer 142 may be oxided to form RuO. In such case, the operation 213 or the nitriding treatment 18 may be repeatedly performable. The RuO on portions of the RuN layer 142 of the EUV photomask 10 can be converted back to RuN.

For a purpose of brevity, only differences from other embodiments are emphasized in the following specification, and descriptions of similar or same elements, functions and properties are omitted. For a purpose of clarity and simplicity, reference numbers of elements with same or similar functions are repeated in different embodiments. However, such usage is not intended to limit the present disclosure to specific embodiments or specific elements. In addition, conditions or parameters illustrated in different embodiments can be combined or modified to have different combinations of embodiments as long as the parameters or conditions used are not in conflict.

One aspect of the present disclosure provides a method of manufacturing a photomask. The method includes: forming a multilayer structure on a substrate; forming a capping layer on the multilayer structure, the capping layer including a ruthenium oxide (RuO) layer; forming a light-absorbing structure on the capping layer; forming a hard mask on the light-absorbing structure; etching the light-absorbing structure to form a recess by using the hard mask as an etch mask, wherein the recess exposes a top portion of the capping layer; and performing a treatment to convert the top portion into a ruthenium nitride (RuN) layer.

One aspect of the present disclosure provides another method of manufacturing a photomask. The method includes: providing a substrate; depositing a multilayer structure on the substrate; forming a capping layer including a RuO layer on the multilayer structure; forming a light-absorbing structure on the capping layer; patterning the light-absorbing structure to expose a top portion of the capping layer; and nitriding the top portion to form a RuN layer surrounded by the light-absorbing structure being patterned.

Another aspect of the present disclosure provides a photomask. The photomask includes: a substrate; a multilayer structure, disposed on the substrate; a capping layer, disposed on the multilayer structure; and a light-absorbing structure, including a recess and disposed on the capping layer, wherein the capping layer includes: a RuO layer; and a RuN layer, disposed on the RuO layer and exposed by the recess.

The foregoing outlines features of several embodiments so that those skilled in the art may better understand aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method of manufacturing a photomask, comprising:
forming a multilayer structure on a substrate;
forming a capping layer on the multilayer structure, the capping layer including a ruthenium oxide (RuO) layer;
forming a light-absorbing structure on the capping layer;
forming a hard mask on the light-absorbing structure;
etching the light-absorbing structure to form a recess by using the hard mask as an etch mask, wherein the recess exposes a top portion of the capping layer; and
performing a treatment to convert the top portion into a ruthenium nitride (RuN) layer.

2. The method of claim 1, wherein the etching of the light-absorbing structure includes laterally removing portions of the light-absorbing structure.

3. The method of claim 1, wherein after performing the treatment, the capping layer includes the RuN layer surrounded by the light-absorbing structure and covering a portion of the RuO layer.

4. The method of claim 1, wherein the RuN layer prevents a carbon (C) atom, a hydrogen (H) atom or a hydrocarbon compound from reacting with or adhering to the RuO layer.

5. The method of claim 1, wherein the light-absorbing structure includes a reflective region and an absorptive region arranged with the reflective region, and the RuN layer is disposed in the reflective region.

6. The method of claim 1, wherein the treatment is a nitriding reaction.

7. The method of claim 6, wherein the nitriding reaction includes using a plasma treatment.

8. The method of claim 6, wherein the nitriding reaction lasts for about 100 seconds (s) to 500 s.

9. A method of manufacturing a photomask, comprising:
providing a substrate;
depositing a multilayer structure on the substrate;
forming a capping layer including a RuO layer on the multilayer structure;
forming a light-absorbing structure on the capping layer;
patterning the light-absorbing structure to expose a top portion of the capping layer; and
nitriding the top portion to form a RuN layer surrounded by the light-absorbing structure being patterned.

10. The method of claim 9, wherein
the light-absorbing structure includes a tantalum boron oxide (TaBO) material over a tantalum boron nitride (TaBN) material, and
the patterning of the light-absorbing structure includes using a first etch gas to etch the TaBO material and a second etch gas different from the first etch gas to etch the TaBN material.

11. The method of claim 9, wherein after the nitriding of the top portion, the capping layer includes the RuN layer covering a portion of the RuO layer.

12. The method of claim 9, wherein the nitriding of the top portion includes a deoxygenation reaction.

13. The method of claim 9, wherein the nitriding of the top portion includes using atmospheric pressure (AP) plasma or inductive couple plasma (ICP).

14. The method of claim 9, wherein the RuN layer and the light-absorbing structure after being patterned isolate the RuO layer from a hydrocarbon compound in an ambient.

15. A photomask, comprising:
a substrate;
a multilayer structure, disposed on the substrate;
a capping layer, disposed on the multilayer structure; and
a light-absorbing structure, including a recess and disposed on the capping layer, wherein the capping layer includes:
a RuO layer; and
a RuN layer, disposed on the RuO layer and exposed by the recess.

16. The photomask of claim 15, wherein the RuN layer is surrounded by the light-absorbing structure.

17. The photomask of claim 15, wherein the RuN layer is surrounded by a portion of the RuO layer below the light-absorbing structure.

18. The photomask of claim 15, wherein the RuO layer has a substantially U-shaped profile from a cross-sectional view.

19. The photomask of claim 15, wherein the light-absorbing structure includes:
a TaBN layer, disposed on the capping layer and surrounding the RuN layer; and
a TaBO layer, disposed on the TaBN layer.

20. The photomask of claim 15, wherein the RuN layer has a thickness which is about 0.01 to about 0.8 times a thickness of the capping layer.
